(19) United States
(12) Patent Application Publication
(10) Pub. No.: US 2008/0197381 A1
(43) Pub. Date: Aug. 21, 2008

(54) SEMICONDUCTOR DEVICE AND METHOD FOR MANUFACTURING SAME

(75) Inventors: Yoshiya Kawashima, Kawasaki (JP); Yoshinao Miura, Kawasaki (JP); Hitoshi Ninomiya, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/029,478

(22) Filed: Feb. 12, 2008

(30) Foreign Application Priority Data
Feb. 15, 2007 (JP) 2007-35044
Jun. 27, 2007 (JP) 2007-168551

(51) Int. Cl. H01L 29/04; H01L 21/336

(52) U.S. Cl. 257/255; 438/198; 257/E29.003; 257/E21.41

(57) ABSTRACT

A semiconductor device is provided with a vertical MOSFET including an N-type drift region that has a {110} crystal plane serving as the main surface thereof, a trench gate structure formed in a trench that has a {100} crystal plane serving as a sidewall surface thereof, and plural P-type column region structures provided in the N-type drift region 3, making up the super-junction structure. The P-type column region structures are disposed so as to be separated from each other in a plan view, and each of the plurality of column structures includes a plurality of column regions of the second conductivity type separated from each other in a cross-sectional view. By applying ion implantation of a P-type dopant to the main surface from a direction vertical to the main surface, the P-type column regions are formed down to sufficiently deeper positions in the drift region due to channeling. By so doing, it is possible to obtain a semiconductor device with an enhanced breakdown voltage. Further, since it is possible that a crystal plane of a channel is the {100} crystal plane, enabling a maximum electron mobility to be obtained, it is possible to increase on-current, so that on-resistance can be reduced.

### CROSS-REFERENCE TO RELATED APPLICATIONS

This application is based upon, claims the benefits of priority of, and incorporates by reference the contents of Japanese Patent Applications No. 2007-035044 filed on Feb. 15, 2007 and No. 2007-168551 filed on Jun. 27, 2007.

### BACKGROUND

1. Field of the Invention

The present invention relates to a semiconductor device and a method for manufacturing the same, and in particular, to a semiconductor device having vertical field effect transistors, and a method for manufacturing the semiconductor device.

2. Description of Related Art

A vertical power MOSFET superior to a conventional lateral MOSFET has been proposed as a MOSFET (a metal-oxide semiconductor field-effect transistor) having a low on-resistance, and a high breakdown voltage. Important characteristics of this kind of a high breakdown voltage MOSFET include a low on-resistance, and a high breakdown voltage. The on-resistance, and the breakdown voltage are dependent on resistivity of a drift layer functioning to relax an electric field intensity, and there exist a relationship of trade-off between the on-resistance, and the breakdown voltage in that the on-resistance can be reduced if the resistivity is lowered by raising impurity concentration in the drift layer, but the breakdown voltage as well becomes lower at the same time. For this reason, there has so far has been limitation to an extent of reduction in on-resistance while maintaining a high breakdown voltage.

As a technology whereby the on-resistance is dramatically reduced while maintaining a high breakdown voltage characteristics of a vertical MOSFET, there has lately been proposed the so-called super-junction structure. FIG. 7 is a partial cross-sectional view of a conventional semiconductor device having the super-junction structure, showing a cell structure of the vertical MOSFET.

A semiconductor device 1 includes an N⁺ semiconductor substrate 32, an N-type drift region 33 formed on the semiconductor substrate 32, functioning to relax an electric field intensity, a P-type base region 34 formed in the N-type drift region 33, an N⁺ type source regions 35 formed in the P-type base region 34, a trench gate structure formed in the P-type base region 34 and a part of the N-type drift region 33, the trench gate structure having a gate insulating films 6 and a gate electrode 7 formed in a trench, an insulating film 8 formed over the trench gate structure, a source electrode 9 formed over the insulating films 8 while being electrically connected with the N⁺ type source regions 35 and the P-type base region 34, a P-type column region 40 formed in the N-type drift region 33 and between the two adjacent trench gate structure, and a drain electrode 11 formed on the back surface of the semiconductor substrate 32. With a semiconductor device in practical use, the cell structure as described is cyclically formed in a plane of a semiconductor chip.

Herein, the semiconductor substrate 32, the drift region 33, and the source region 35 are of the same conductivity type (in this case, N-type). Further, the base region 34, and the column region 40 are of a conductivity type (in this case, P-type) opposite from that of the N-type. Further, respective dopant doses of the N-type drift region 33, and the P-type column region 40 are set substantially equal to each other.

Now, there is described hereinafter operation of the semiconductor device 1. If a reverse biased voltage is applied across the drain and the source when a bias voltage is not applied between the gate and the source (a MOSFET is in the OFF state), a depletion layer spreads from two PN junctions formed between the P-type base region 34 and the N-type drift region 33 and between the P-type column region 40 and the N-type drift region 33, respectively, thereby curbing leakage current between the drain and the source. More specifically, an interface between the P-type column region 40 and the N-type drift region 33 is extended in the vertical direction between the drain and the source, so that the depletion layer spreads in the lateral direction from the interface.

If depletion occurs to a region for a distance “d” in FIG. 7, the depletion layer is linked with an adjacent depletion layer spreading from the adjacent PN junction formed between the adjacent P-type column region 40 and the N-type drift region 33 to each other, so that the P-type column regions 40 and the N-type drift regions 33, in whole, will undergo depletion (not shown). As a result, the breakdown voltage of the semiconductor device 1 is not dependent on impurity concentration in the N-type drift region 33, but will be dependent only on a thickness of the N-type drift region 33. Accordingly, with the adoption of the super-junction structure, it becomes possible to reduce the on-resistance even if the impurity concentration in the N-type drift region 33 is increased while maintaining a high breakdown voltage. Further, since the breakdown voltage can be controlled according to the thickness of the N-type drift region 33, it is possible to diversify a combination of the on-resistance of the semiconductor device 1, and the breakdown voltage thereof.

In Patent Document 1, there has been disclosed a semiconductor device of the super-junction structure although this semiconductor device represents an example of a lateral MOSFET in contrast to the semiconductor device 1.

With the semiconductor device having the super-junction structure, the highest breakdown voltage can be obtained in the case where a region of a reverse conductivity type (in this case, P-type), formed in an N-type drift region, is formed to a thickness equivalent to that of the drift region, as shown in Patent Document 1. In order to implement such a structure as described, there have been proposed a method for forming a super-junction structure having a P-type region and N-type region, arranged in parallel to each other, within a chip plane, in such a way as to undergo epitaxial growth by the given depth, as described in Non-patent Document 1, and a method for forming a super-junction structure by applying an oblique ion implantation method after forming a deep trench penetrating through a drift layer, as described in the same literature.

Further, literature on the related art associated with the present invention includes Patent Documents 2 to 5 besides Patent Document 1 and Non-patent Document 1.
Patent Document 1: Japanese Unexamined Patent Application Publication No. 2001-135819 (JP-A No. 135819/2001)
Patent Document 2: Japanese Unexamined Patent Application Publication No. 2000-208527 (JP-A No. 208527/2000)
Patent Document 3: Japanese Unexamined Patent Application Publication No. 2005-191268 (JP-A No. 191268/2005)
Patent Document 4: Japanese Unexamined Patent Application Publication No. 2001-313393 (JP-A No. 313393/2001)
Patent Document 5: Japanese Unexamined Patent Application Publication No. 2002-299622 (JP-A No. 299622/2002)
Non-patent Document 1: Proceedings of the 12^{th} International symposium on Power Semiconductor Devices & ICs, P. 73, 2000

The inventors, however, have considered that with any of the methods described, process steps become complex, and are difficult to control, leading to difficulty in controlling device properties.

In general, the vertical MOSFET is formed such that a crystal plane for forming a channel of the MOSFET corresponds to a silicon (100) crystal plane having a plane direction excellent in terms of reliability of the gate insulating film, and carrier mobility. If use is made of a silicon (100) substrate in which an orientation-flat (hereinafter written as OF) plane is oriented (001), a crystal axis direction [001] vertical to the OF plane, and a crystal axis direction [010] parallel to the OF plane can be crystal axis directions crossing each other at right angles, respective, on a silicon substrate plane, as shown in FIG. 8. If channel planes are formed vertically (or in parallel to) to the respective crystal axis directions, any of the channel planes can rendered the silicon (100) plane. By so doing, for a trench gate structure of the MOSFET, either a tetragonal lattice-like arrangement along two orthogonal axes, or stripe-like arrangement along only one axis becomes selectable, so that flexibility in layout designing is obtained. Owing to those advantages, the silicon (100) substrate has been used for the vertical MOSFET commonly used.

However, in the case of using a method for forming the P-type region (the column region) by applying the ion implantation, or solid state diffusion as the method for forming the super-junction structure having the P-type region and the N-type region, arranged in parallel to each other, within the drift region, as shown in FIG. 7, the silicon (100) substrate will have a breakdown voltage of the device restricted to a given amount for the following reason. In order to attain a higher breakdown voltage, for example, at 100V, it becomes necessary to have a drift region at least on the order of 5 μm in thickness. With an ion implanter commonly used in the manufacture of a semiconductor device, if acceleration energy is increased to a degree, or higher, ion current as obtained will considerably decrease, and consequently, acceleration energy in practical use is not more than about 2 MeV. When boron is used as a dopant for a P-type column, it is difficult to form a P-type column region not less than about 3 μm in thickness within the silicon (100) substrate. Further, in the case of using the solid state diffusion, diffusion of the P-type dopant, in the lateral direction, will become pronounced along with an increase in depth of the drift region, so that it is difficult to form the super-junction structure as separated down to a sufficient depth.

### SUMMARY

In one feature of the present invention, there is provided a semiconductor device comprising a drift region of a first conductivity type, having a {110} crystal plane serving as a main surface thereof, a trench gate structure formed in a trench that has a {100} crystal plane serving as a sidewall surface thereof, and column structures of a second conductivity type provided in the drift region, formed so as to be separated from each other with spacing interposed therebetween, as seen in a plan view. Furthermore, each of the plurality of column structures includes a plurality of column regions of the second conductivity type separated from each other along a direction vertical to the main surface.

In another feature of the present invention, there is provided a method for manufacturing a semiconductor device, the method comprising the steps of forming a drift region of a first conductivity type, having a {110} crystal plane serving as a main surface thereof, forming a trench that has a {100} crystal plane serving as a sidewall surface thereof, in the drift region, forming a gate insulating film and a gate electrode in the trench, and forming column structures of a second conductivity type in the drift region, so as to be separated from each other with spacing interposed therebetween, as seen in a plan view. Furthermore, each of the plurality of column structures are formed so as to include a plurality of column regions that are separated from each other along a direction vertical to the main surface.

According to those features, since the column structures can be formed at sufficiently deeper positions in the drift region, it is possible to improve the breakdown voltage.

The drift region having the {100} crystal plane serving as the main surface thereof is formed, and by applying ion implantation of a dopant thereto at plural acceleration energies differing from each other, the plurality of the column regions are formed so as to be separated from each other along the direction vertical to the main surface. By so doing, the column structures can be formed down to sufficiently deep positions in the drift region with greater ease. This is because the {110} crystal plane (a (110) crystal plane, and crystal planes including all crystal directions equivalent thereto) has a lattice structure with a wider spacing between atoms as compared with a lattice structure of the {100} crystal plane (a (100) crystal plane, and crystal planes including all crystal directions equivalent thereto), as shown in FIGS. 9A, 9B. FIGS. 9A, and 9B each are a schematic diagram showing atomic arrangement of the (100) crystal plane, and the (110) crystal plane of a silicon, respectively. In the figures, black circles indicate silicon atoms.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a partially cross-sectional view of a first embodiment of a semiconductor device 15 according to the present invention;

FIG. 2 is a graph showing depth wise distribution of boron concentration;

FIG. 3 is a graph showing voltage-current waveform characteristics of a semiconductor device 1, and the semiconductor device 15, respectively;

FIG. 4 is a view showing results of a simulation for a flow path of avalanche current the semiconductor device 15;

FIG. 5 is a partially cross-sectional view of a second embodiment of a semiconductor device 100 according to the present invention;

FIG. 6 is a conceptual top view of the semiconductor device 100;

FIG. 7 is a partial cross-sectional view of a conventional semiconductor device according to a conventional technology;

FIG. 8 is a view showing respective crystal axis directions, and plane direction on a (100) substrate in which a (001) crystal plane serving as an OF plane;

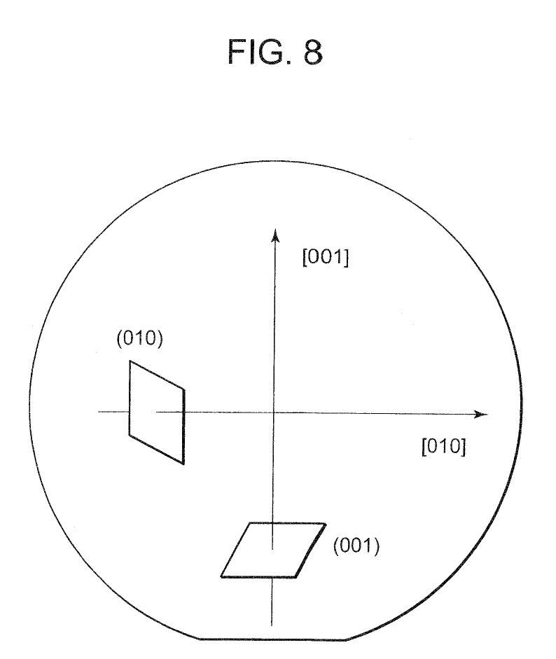

FIGS. 9A, and 9B each are a schematic diagram showing atomic arrangement of the (100) crystal plane, and the (110) crystal plane of a silicon, respectively;

FIG. 10 is a partially cross-sectional view of a third embodiment of a semiconductor device 201 according to the present invention

FIGS. 11A to 11D each are a partially cross-sectional view showing a method for manufacturing the semiconductor device 201;

FIGS. 12A, and 12B are a partial cross-sectional view of the semiconductor device 201, and an electric field distribution view at the time of a reverse bias being applied in the vicinity of column regions, respectively;

FIGS. 13A, and 13B are a partial cross-sectional view of the semiconductor device 15, and an electric field distribution view at the time of a reverse bias being applied in the vicinity of column regions, respectively; and

FIG. 14 is a graph showing voltage-current waveform characteristics of the semiconductor device 201, and the semiconductor device 15, respectively.

### DETAILED DESCRIPTION OF THE PREFERRED EMBODIMENTS

The present invention will now be described herein with reference to illustrative embodiments. Those skilled in the art will recognize that many alternative embodiments can be accomplished using the teachings of the present invention and that the present invention is not limited to the embodiments illustrated for explanatory purposes.

Preferred embodiments of a semiconductor device, and a method for manufacturing the same, according to the present invention, are described in detail hereinafter with reference to the accompanying drawings. In the respective drawings, identical constituents are denoted by like reference numerals, respectively, thereby omitting duplication in description.

### First Embodiment

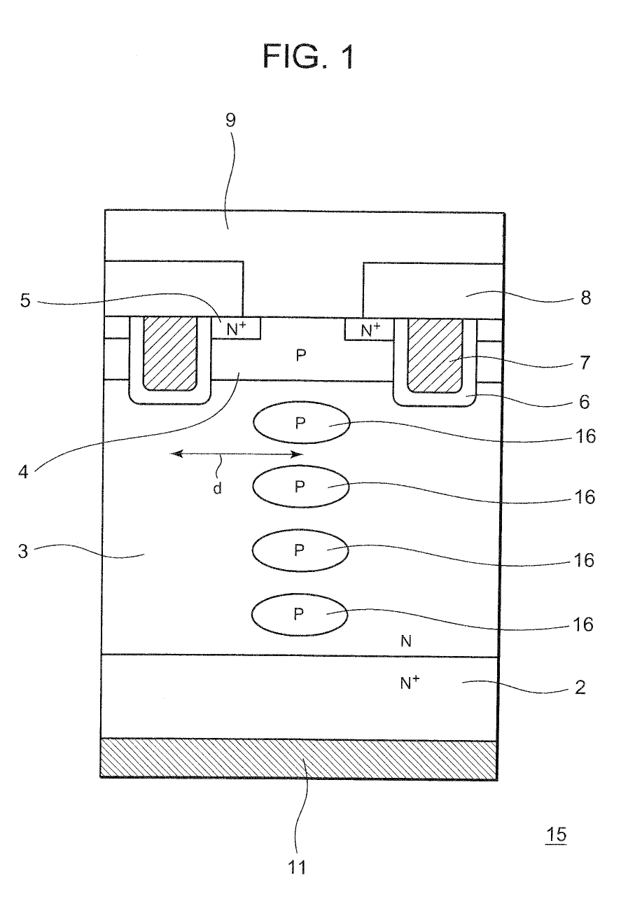

FIG. 1 is a partially cross-sectional view showing a first embodiment of a semiconductor device 15 according to the present invention. The semiconductor device 15 is provided with a cell structure of a vertical MOSFET including a semiconductor substrate 2 of an N⁺ conductivity type, having a {110} crystal plane serving as a main surface thereof, an N-type drift region 3 provided on the main surface of the semiconductor substrate 2, and P-type column regions 16 provided in the N-type drift region 3, making up the super-junction structure. The P-type column regions 16 are separated into plural pieces along a direction vertical to the main surface (in the direction of the thickness of the N-type drift region: hereinafter referred to as “an axial direction of the main surface”). In other words, the P-type column regions 16 plural in numbers, each being separated by a portion of the N-type drift region 3, with a given thickness, are disposed at, for example, four sites along the axial direction of the main surface. Those four P-type column regions 16 in a group are to be called a column structure. The semiconductor substrate 2 is typically a silicon substrate. If the main surface is the (110) crystal plane, a direction vertical thereto is a crystal axis direction [110].

To describe in more details, the semiconductor device 15 includes the semiconductor substrate 2 of an N⁺ conductivity type, the N-type drift region 3 formed over the semiconductor substrate 2, functioning as a drift layer, a P-type base region 4 formed in the N-type drift region 3, source regions 5 of the N⁺ conductivity type, formed in the base region 4, gate insulating films 6, gate electrodes 7 formed on each of the gate insulating films 6, an insulating film 8 formed over the gate electrode 7, a source electrode 9 formed over the insulating films 8 while being continuous with the source regions 5, and a drain electrode 11 formed on the back surface of the semiconductor substrate 2. The gate electrode 7 is provided in a trench gate structure formed in the base region 4 through the intermediary of the gate insulating film 6. In FIG. 1, a plurality of trench gate structures are illustrated. Incidentally, the respective trench gate structures may be joined to each other to be formed a single trench gate structure. Further, the P-type column regions 16 are positioned between the gate electrodes 7 adjacent to each other, as seen in a plan view. With a semiconductor device in practical use, the cell structure as described is cyclically formed in a chip plane.

Herein, the semiconductor substrate 2, the N-type drift region 3, and the source regions 5 are of an identical conductivity type (in this case, the N-type). Further, the base region 4, and the column regions 16 are of a conductivity type (in this case, the P-type) opposite from that of the N-type drift region 3. Furthermore, respective dopant doses of the N-type drift region 3, and each of the P-type column regions 16 are set substantially equal to each other.

There will be described hereinafter a method for manufacturing the semiconductor device 15 by way of example. This manufacturing method includes the step of forming the N-type drift region 3 on the main surface of the semiconductor substrate 2, the main surface being the {110} crystal plane, and the step of forming the P-type column regions 16 in the N-type drift region 3. The N-type drift region 3 can be formed as an N-type epitaxial layer. Accordingly, the N-type drift region 3 has the {100} crystal plane to serve as the main surface thereof.

The P-type column regions 16 are formed by ion implantation, and heat treatment. The ion implantation is applied by varying acceleration energy in magnitude in stages. If resistivity and thickness of the N-type drift region 3 are set to, for example, 1 Ω·cm, and 8 μm, respectively, the ion implantation is applied to the N-type drift region 3 on the following conditions. That is, conditions of ion species; 11B⁺, acceleration energy; in 4 stages of 150, 500, 1000, 1500 keV, respectively, from a lower speed side, and a dopant dose: 3.0×10¹² atoms/cm², for example. By so doing, the P-type column regions 16 are formed in such a way as to be separated into plural pieces along the axial direction of the main surface.

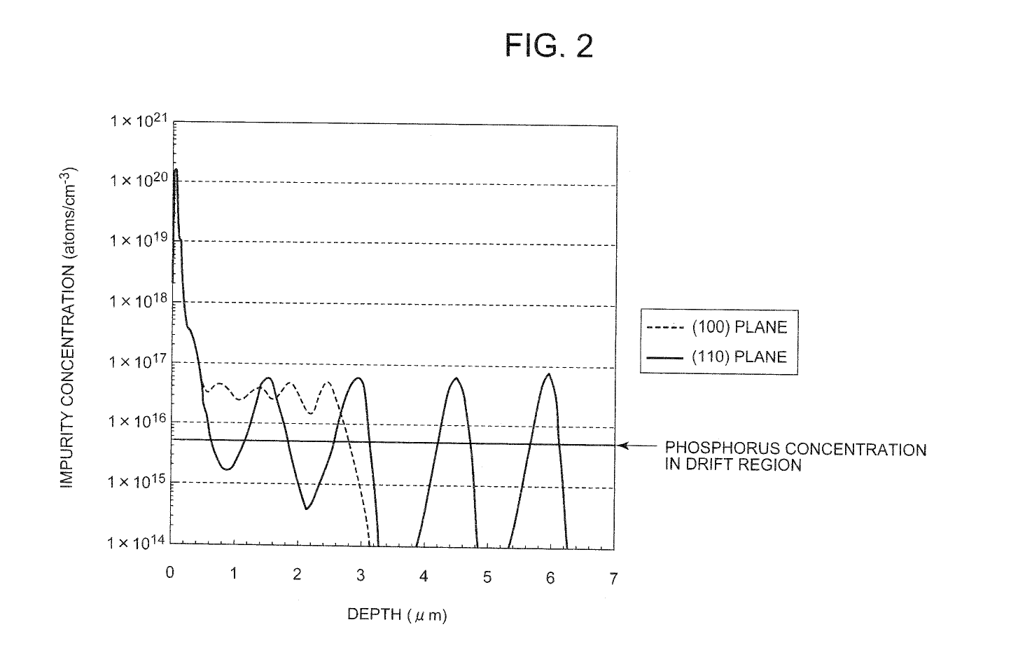

FIG. 2 is a graph showing depth wise distribution of boron concentration, in the semiconductor device 15 manufactured on those conditions, as compared with that for the semiconductor device 1 using the semiconductor substrate 32 with the {100} crystal plane serving as the main surface thereof. The semiconductor device 15 has features in respect of two points, that is, (1) boron concentration even at the same acceleration energy is distributed to a depth twice, or more as deep as a depth for a conventional case, and (2) regions of boron concentration lower than phosphorous concentration of the N-type drift region are formed between peaks of distributions of respective implantations differing in acceleration energy from each other.

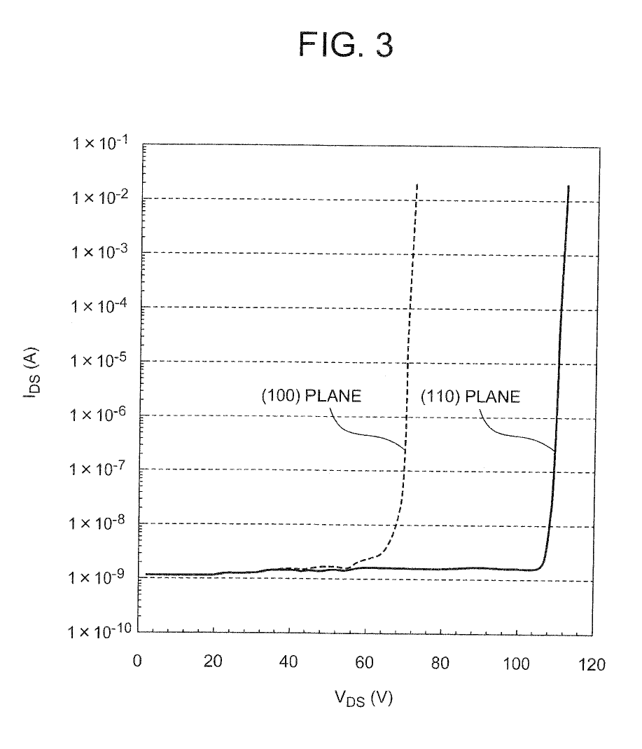

FIG. 3 is a voltage-current waveform graph obtained by plotting drain current while varying a bias voltage applied across the drain and the source. Owing to the feature described under (1) as above, the effect of the super-junction structure is sufficiently exhibited down to deeper regions, and with the semiconductor device 15, a point where an avalanche phenomenon occurs is found higher by 30V, or more as compared with the case of the conventional semiconductor device.

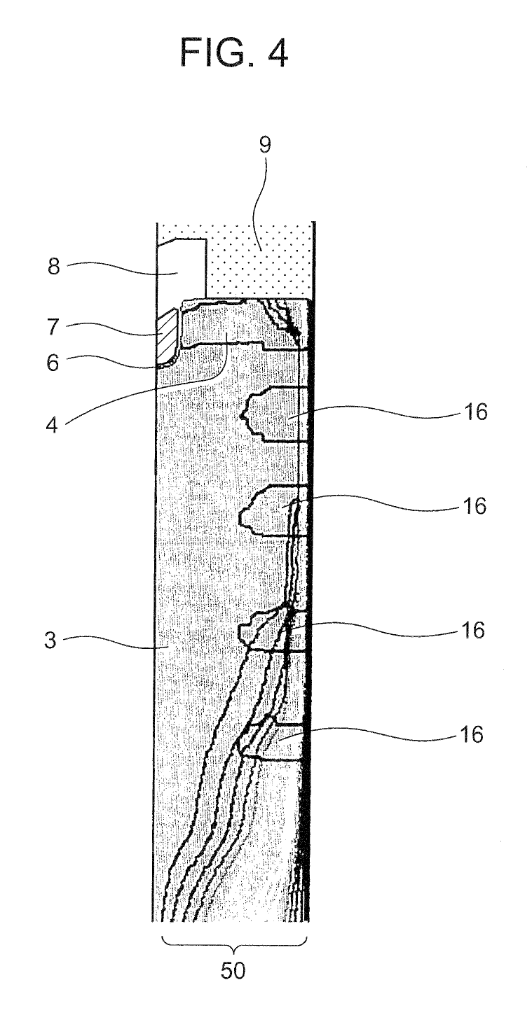

FIG. 4 shows results of a simulation, showing a flow path of avalanche current 50 when a bias in excess of a breakdown voltage is applied across the drain and the source of the semiconductor device 15. The avalanche current 50 is found flowing from the drain electrode 11 (not shown) toward the source electrode 9 so as to pass through the column regions 16. The avalanche current 50 flows in such a state in which it spreads in the lateral direction on the lower side of the N-type drift region 3, adjacent to the semiconductor substrate 2, but converges on a region around the central axis of the column regions 16 as it flows toward the source electrode 9 via the base region 4. That is, since the avalanche current 50 flows through regions away from the trench gate structure, it is possible to prevent to damage the gate insulating films 6 of the MOSFET.

The reason for this is as follows. In the case where a reversed high electric field is applied across the N-type drift region 3 and the P-type base region 4, when the MOSFET is in the OFF state, and each adjoining depletion layers occurring between the N-type drift region 3 and the respective column structures is spread and developed into being joined to each other, thereby causing the drift region 3 in whole to turn into a single depletion layer, the reversed electric field is applied to the single depletion layer in depth direction thereof. An electric field produced by acceptor ions having negative charge and donor ions having positive charge is acting on a PN junction formed between the P-type base region 4 and the N-type drift region 3, and respective PN junctions formed between the P-type column regions 16 and the N-type drift region 3. If the direction of the electric field produced between the acceptor ions and the donor ions coincides with the direction of the reversed electric field acting on the single depletion layer, both the electric fields reinforce each other to thereby cause an intense electric field to be applied thereto, so that those regions are susceptible to breakdown. If the column regions are separated from each other, the number of regions susceptible to breakdown (breakdown points) will increase to that extent. In FIG. 4, the four column regions 16 are formed, and the PN junction in each of the column regions 16 undergoes breakdown one after another, so that the avalanche current 50 undergoes concentration in these regions.

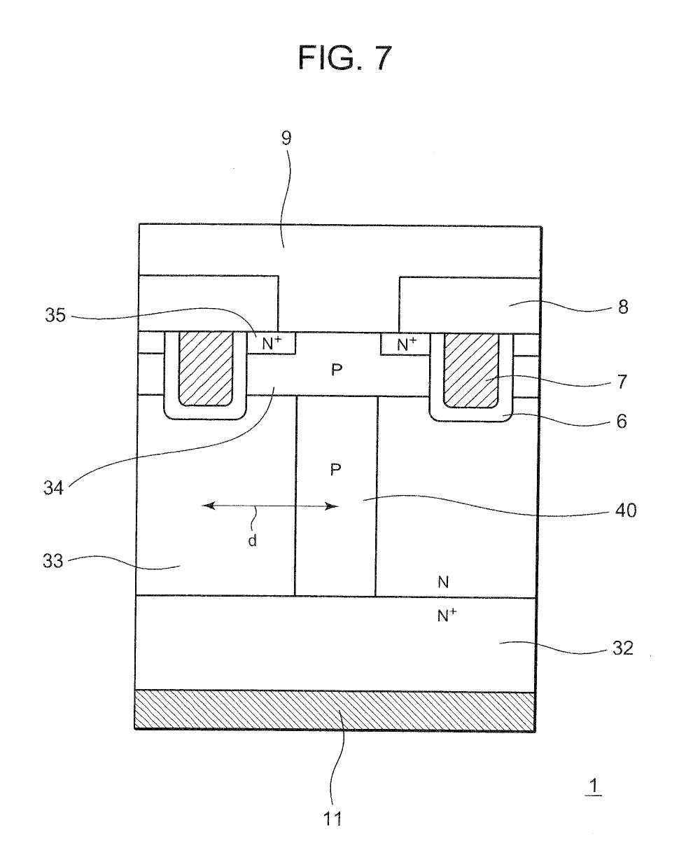

If the column regions are not separated from each other, as shown in FIG. 7, the breakdown point will exist only at one site that the PN junction formed between the P-type column region 40 and the N⁺ semiconductor substrate 32. Accordingly, it is not possible to prevent avalanche current flowing through the vicinity of the trench gate structure. As a result, the gate insulating film will be damaged.

In contrast, with the column structure having plural column regions separated from each other, it is possible to create plural breakdown points to thereby facilitate breakdown in the column structure, so that the avalanche current can be concentrated in the column structure. Accordingly, the gate insulating film can be protected from being damaged caused by the avalanche current.

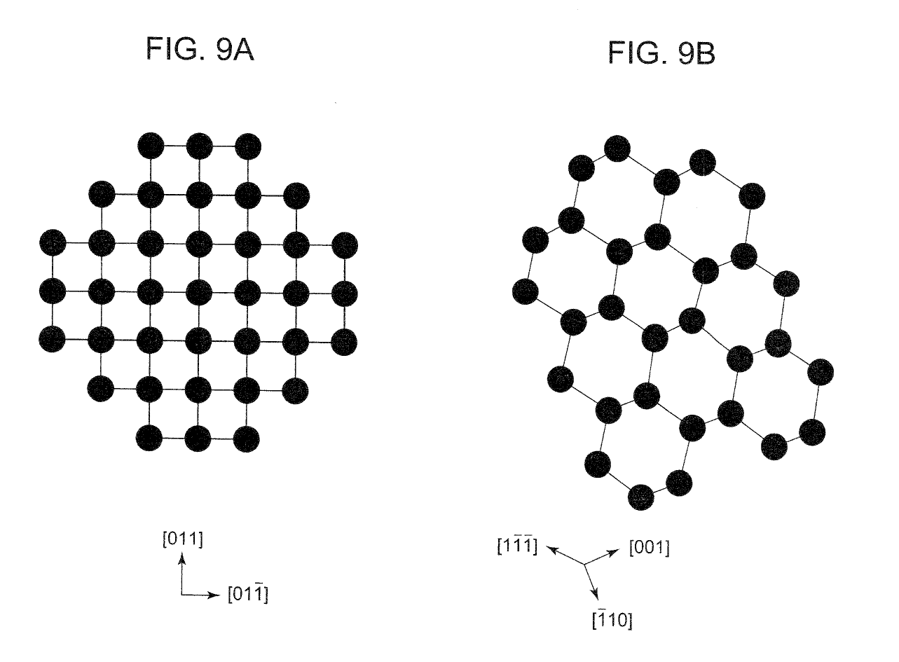

With the semiconductor device 15, the N-type drift region 3 is provided on the main surface of the semiconductor substrate 2, the main surface thereof being the {110} crystal plane. Accordingly, the P-type column regions 16 can be formed at sufficiently deep positions in the N-type drift region 3. This is because the {110} crystal plane, as shown in FIG. 9B, has a lattice structure with a wider spacing between atoms as compared with a lattice structure of the {100} crystal plane, as shown in FIG. 9A, so that a dopant can be disposed in regions at greater depths due to channeling upon ion implantation and thermal diffusion.

Further, since the P-type column regions 16 are formed by the ion implantation and the heat treatment, in contrast to the case of the method described in Non-patent Document 1, it is possible to prevent the process steps from becoming complex. In consequence, it becomes easier to control the process steps, thereby leading to easier control of the device properties.

Thus, with the present embodiment, it is possible to obtain the semiconductor device 15 having a lower on-resistance and a higher breakdown voltage.

Now, in Patent Document 2, it has been disclosed that a plane direction of the main surface of a substrate on which a device is formed is to correspond to the {110} crystal plane. However, with the method according to Patent Document 2, P-type column regions are consecutively formed in the axial direction of the main surface. Accordingly, the breakdown point is exist only at one site similarly to the semiconductor device 1, this will not be possible to prevent avalanche current flowing through the vicinity of the trench gate structure. As a result, the gate insulating film will be damaged.

Because there is a possibility that avalanche breakdown occurring typically caused by a surge voltage, it is important to design a device with sufficient resistance thereto. In the case of the semiconductor device 15, the P-type column regions 16 are separated into plural pieces along the axial direction of the main surface, so that the problem described as above can be prevented.

### Second Embodiment

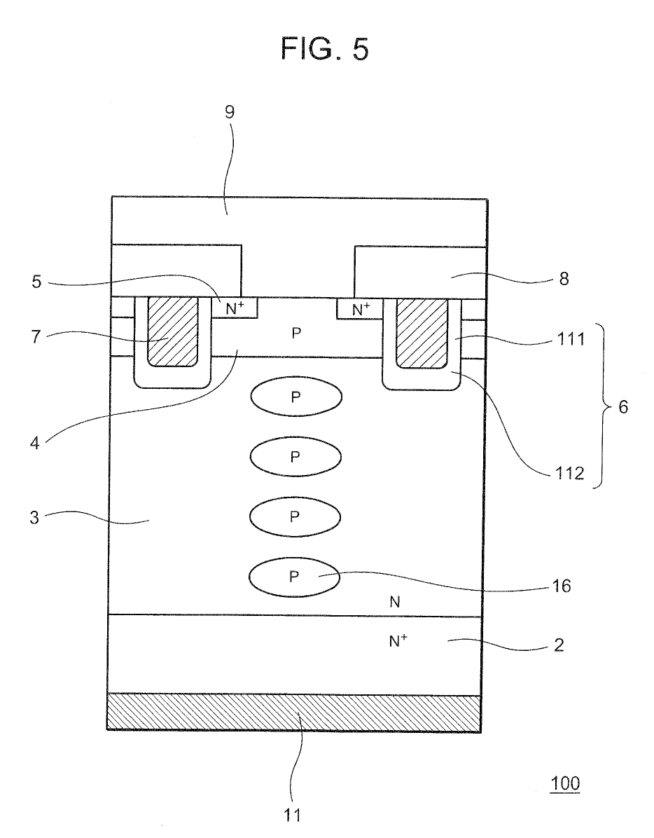

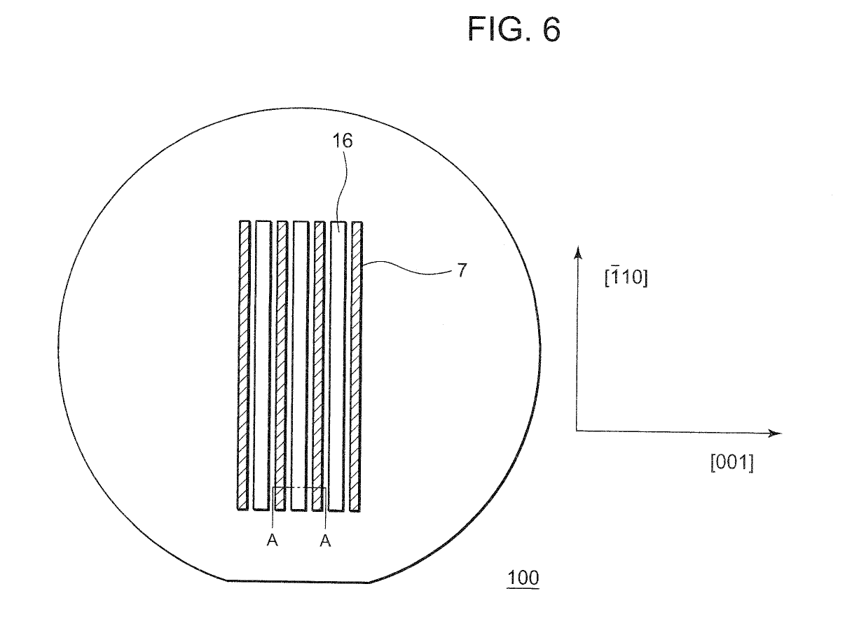

FIG. 5 is a partially cross-sectional view showing a second embodiment of a semiconductor device 100 according to the present invention. Further, FIG. 6 is a conceptual top view of the semiconductor device 100. FIG. 5 is a cross-sectional view taken on line A-A in FIG. 6. As shown in FIG. 6, with the semiconductor device 100, P-type column regions 16, and gate electrodes 7 are disposed in a stripe-like fashion, as seen in a plan view. In FIG. 5, a plurality of trench gate structures are illustrated. Incidentally, the respective trench gate structures maybe joined to each other at one end, for example, to be formed a single trench gate structure. A direction in which those constituents are extended corresponds to a crystal axis direction [−110]. A direction vertical to the crystal axis direction [−110] is a crystal axis direction [001]. That is, the P-type column regions 16, and the gate electrodes 7 are formed in a stripe-like fashion so as to be in parallel with the crystal axis direction [−110] on the (110) crystal plane of a semiconductor substrate 2.

As shown in FIG. 5, for a gate insulating film 6 formed in such a way as to surround the gate electrode 7 in a trench gate structure, use is made of a silicon oxide film. With the semiconductor device 100, a sidewall surface of the trench gate structure is the (001) crystal plane, and a bottom surface of the trench gate structure is the (110) crystal plane. Herein, because a rate of oxidation on the (110) crystal plane is higher than that on the (001) crystal plane, a gate insulating film 112 on the bottom surface of the trench gate structure is formed to a thickness greater than a thickness of a gate insulating film 111 formed on the sidewall surface thereof. As a result, an electric field applied to the bottom surface of the trench gate structure by the agency of a bias applied across the source and the drain and is weakened, thereby enabling a breakdown voltage to be increased.

Further, since it is possible that a crystal plane of a MOSFET, for forming a channel, is the (100) crystal plane corresponding to a plane direction of a silicon substrate, enabling a maximum electron mobility to be obtained, it is possible to increase on-current, so that on-resistance can be reduced. The semiconductor device 100 is the same as the semiconductor device 15 in terms of makeup in other respects, and an effect thereof.

Now, in Patent Document 2, it has been disclosed that the MOSFET has a planar gate structure that having gate insulating films and gate electrodes being formed on the main surface of the semiconductor substrate. Since the crystal plane of the semiconductor substrate corresponds to the {110} crystal plane, thicker gate insulating films will be formed and a channel is formed in the {110} crystal plane, that will limit reducing on-resistance of the MOSFET.

Now, US 2002/0104988 A1 discloses a semiconductor device having a trench gate structure that is formed in a substrate having substrate plane orientation of (110). The side walls of a trench where channels are formed are in (100) planes. However, with the semiconductor device according to US 2002/0104988 A1, column structures are not formed. Therefore, it is impossible to improve the breakdown voltage.

### Third Embodiment

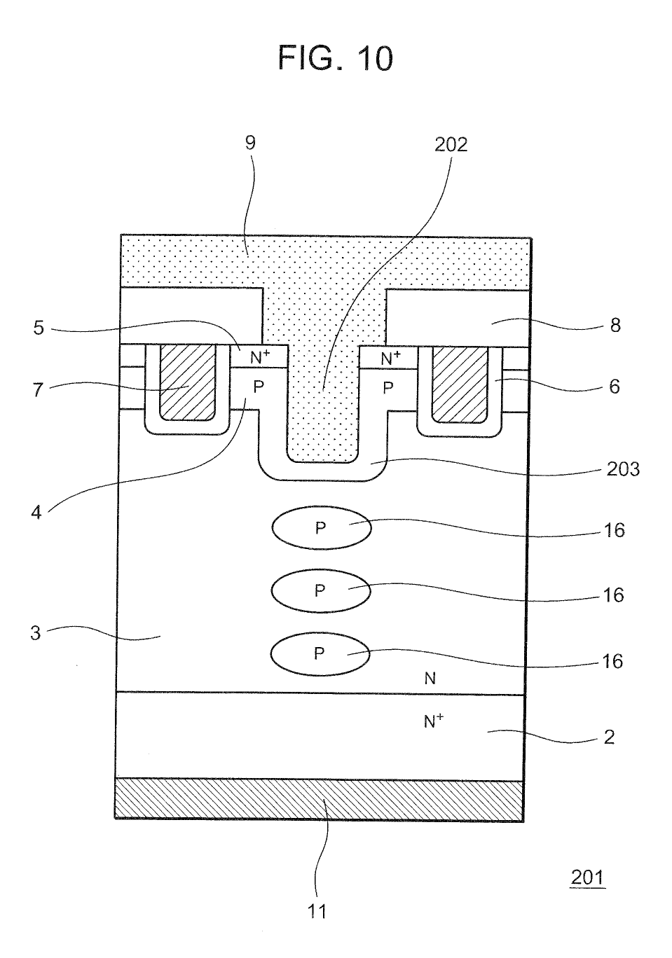

FIG. 10 is a partially cross-sectional view showing a third embodiment of a semiconductor device 201 according to the present invention. As is the case with the semiconductor device 15, the semiconductor device 201 is provided with a vertical MOSFET including a semiconductor substrate 2 having the {110} crystal plane serving as a main surface, an N-type drift region 3provided on the main surface of the semiconductor substrate 2, and P-type column regions 16 provided in the N-type drift region 3, making up the super-junction structure. Further, with the semiconductor device 201, a contact trench 202 is formed above the P-type column regions 16. Still further, a P-type region 203 is formed along a sidewall surface and a bottom surface of the contact trench 202, and a source electrode 9 is provided inside the contact trench 202.

Herein, the contact trench 202 is formed such that a bottom part thereof is positioned at a depth greater than that for the base region 4, as seen in a cross-sectional view. Further, the contact trench 202 is positioned between gate electrodes 7 adjacent to each other, as seen in a plan view, and is filled up with the source electrode 9.

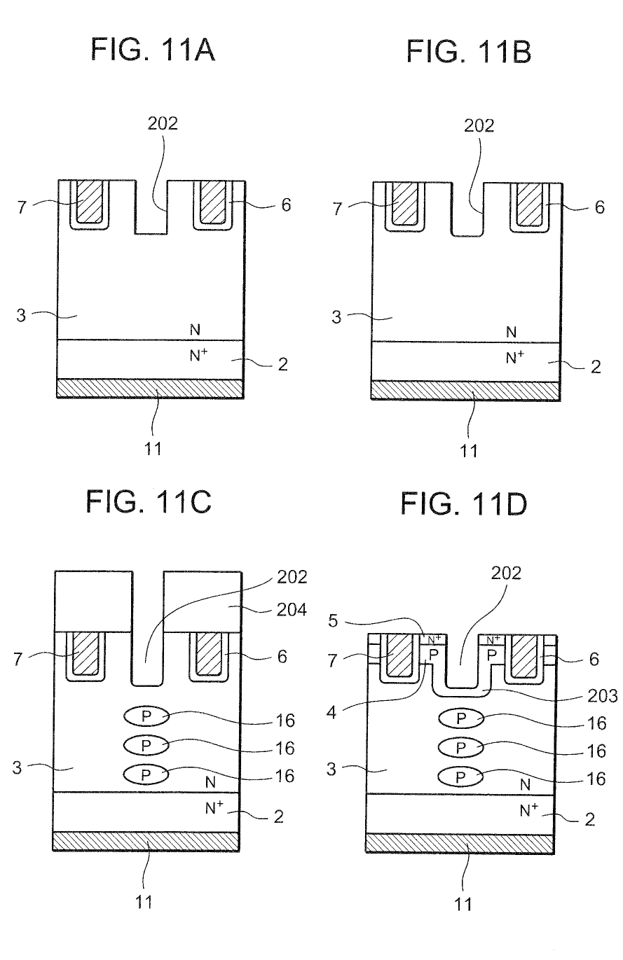

There is described hereinafter an example of a method for manufacturing the semiconductor device 201 with reference to FIGS. 11A to 11D. The method for manufacturing the semiconductor device 201, up to the step of forming the N-type drift region 3, is the same as that for the semiconductor device 15. Thereafter, before forming the P-type column regions 16, the contact trench 202 is newly formed between the respective gate electrodes 7 of trench gate structures adjacent to each other in the N-type drift region 3, as seen in a plan view, by dry etching and so forth (FIG. 11A). Further, thermal oxidation is applied to the semiconductor substrate 2, and then the corners of a bottom part of the contact trench 202 are rounded off by wet etching and so forth (FIG. 11B).

Subsequently, a photomask 204 is formed, and then ion implantation of a P-type dopant is applied through the contact trench 202 while varying acceleration energy in stages (FIG. 11C). As is the case with the semiconductor device 15, if resistivity and thickness of the N-type drift region 3 are set to, for example, 1 Ω·cm, and 8 μm, respectively, and the contact trench 202 is formed to a depth of 1 μm, the ion implantation may be applied with acceleration energy smaller in magnitude as compared with the case of the semiconductor device 15 for formation of P-type column regions 16 in the N-type drift region 3. The ion implantation is applied on conditions that ion species is 11B⁺, acceleration energy is applied in 3 stages of 20, 320, 500 keV, respectively, and a dopant dose is 3.0×10¹² atoms/cm², for example. By so doing, the P-type column regions 16 are formed at three sites, respectively, having a peak concentration at the same depths as respective depths of three sites of the P-type column regions 16 where ion implantation is applied at acceleration energy of 500, 1000, 1500 keV, respectively, among the P-type column regions 16 of the semiconductor device 15.

Subsequently, for formation of the base region 4, ion implantation of the P-type dopant is applied via a part where the contact trench 202 is formed (FIG. 11D). The ion implantation of the P-type dopant is applied by rotating the semiconductor substrate 2 kept at a tilt angle of, for example, 7 degrees continuously, or once every 60 degrees (or, any of angles obtained by dividing 360 degrees by an integer). By so doing, the P-type region 203 is formed along the sidewall and the bottom surface of the contact trench 202. Further, the source regions 5 are formed by ion implantation. Still further, the source electrode 9 is embedded in the contact trench 202, thereby forming the semiconductor device 201 (FIG. 10). The semiconductor device 201 manufactured by the method described as above will be structured such that the PN junction interfaces are extended in the direction vertical to the main surface of the semiconductor substrate 2 even in a region at a depth corresponding to the depth of the P-type column region 16 formed by the ion implantation with the lowest acceleration energy of 150 keV among the P-type column regions 16 of the semiconductor device 15.

In this case, since the contact trench 202 is formed such that the bottom part thereof reaches a position in the N-type drift region 3, at a depth greater than a depth of the base region 4, a PN junction formed between the base region 4 and the N-type drift region 3 is extended not only in a direction parallel to the main surface of the semiconductor substrate 2 but also in the axial direction of the main surface. Herein, the position at the depth greater than the depth of the base region 4 refers to a position deeper than a position of a portion of the base region 4, in contact with the gate insulating film 6, excluding the P-type region 203. In contrast, with the semiconductor device 15, the PN junction formed between the base region 4 and the N-type drift region 3 is formed so as to be extended only in the direction parallel to the main surface of the semiconductor substrate 2 (FIG. 1).

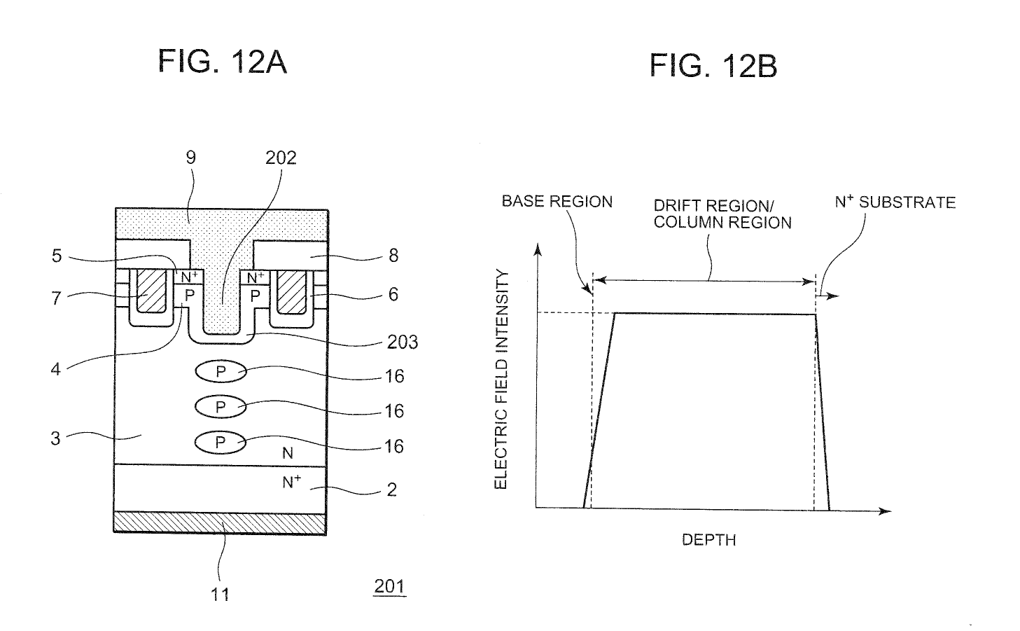

FIG. 12B shows average electric field distribution due to a reverse bias within the semiconductor device 201 when the MOSFET is in the OFF state. Since the contact trench 202 is filled up with the source electrode 9, a spread of a depletion layer, toward the region of the source electrode 9, is suppressed, an extent to which a slight decrease in electric field intensity is observed at a position deeper than the PN junction formed between the base region 4 and the N-type drift region 3. However, thanks to the effect of the super-junction structure, obtained due to the PN junction formed between the P-type region 203 and the N-type drift region 3, the decrease in the electric field intensity as a whole is found restrained to a minimum.

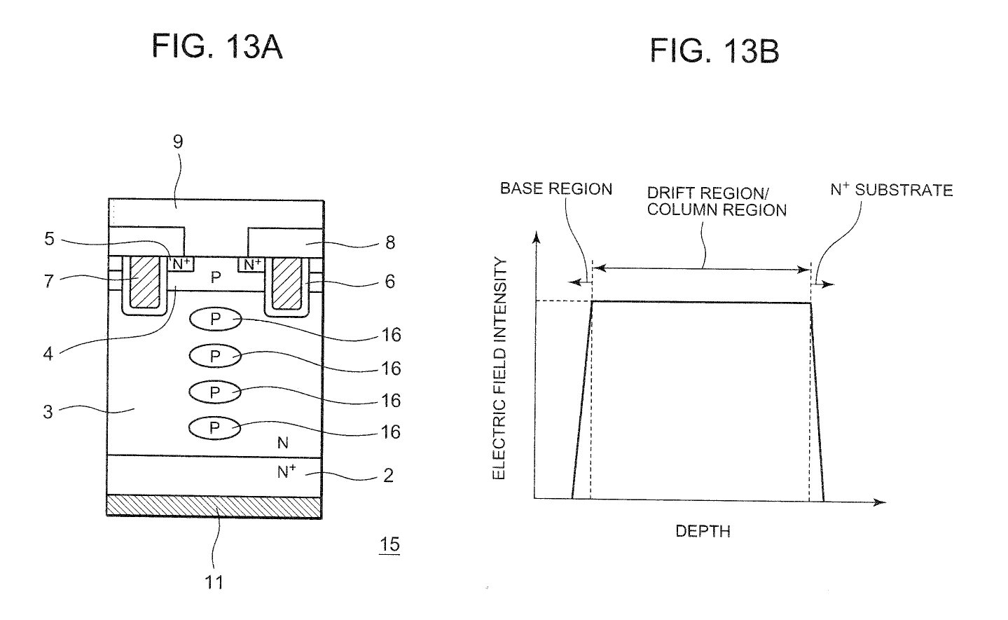

FIG. 13B shows similar electric field distribution in the case of the semiconductor device 15. In the figure, a given electric field intensity is found kept in a region ranging from the interface formed between the semiconductor substrate 2 and the drift region 3 to the PN junction formed between the base region 4 and the drift region 3. Further, depthwise integrated value of electric field intensity is substantially proportional to the breakdown voltage of the device.

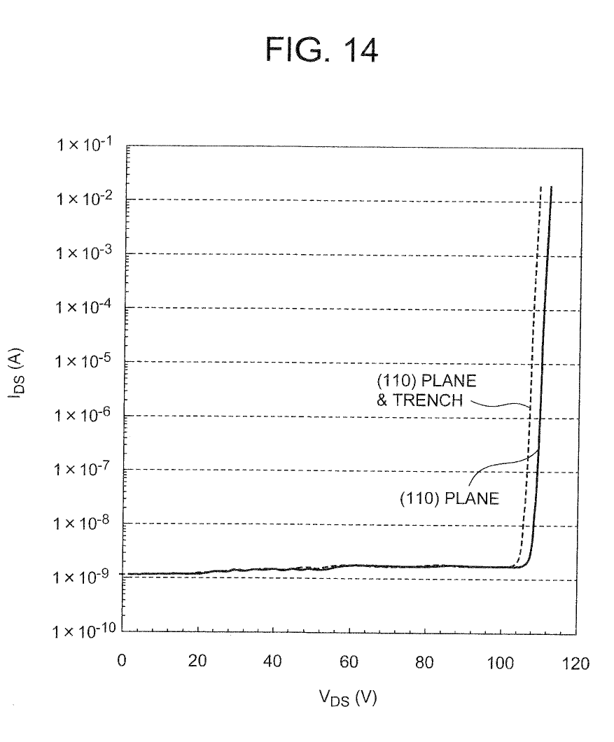

FIG. 14 is a voltage-current waveform graph obtained by plotting drain current while varying a bias voltage applied across the drain and the source, to thereby compare the semiconductor device 201 (the dotted line) with the semiconductor device 15 (the solid line). A point where an avalanche phenomenon that causes the drain current of the semiconductor device 201 to abruptly increase will occur is found lower by about 2V as compared with the case of the semiconductor device 15, but is found higher by about 30V or more as compared with that in the case of the semiconductor device 1, shown in FIG. 3. With the semiconductor device 201, by forming the contact trench 202, it is possible to do without application of ion implantation at high acceleration energy of 1500 keV, poor in throughput, and to decrease the number of application times of the ion implantation from three to four while obtaining the effect of the super-junction structure, bearing comparison with the semiconductor device 15.

Further, in a stage, as shown in FIG. 11C, among process steps for manufacturing the semiconductor device 201, the ion implantation of the P-type dopant is applied by utilizing the photomask 204 for the formation of the P-type column regions 16 while rotating the semiconductor substrate 2 kept at a tilt angle of, for example, 5 degrees continuously, or once every 60 degrees (or, any of angles obtained by dividing 360 degrees by an integer), thereby enabling concentration in the P-type region 203 formed along the sidewall and the bottom surface of the contact trench 202, to increase, and also, a break down voltage can be enhanced. The ion implantation is applied on conditions that ion species is 11B⁺, acceleration energy is applied at 10 keV, and a dopant dose is 3.0×10¹³ atoms/cm².

Further, since the contact trench 202 is filled up with the source electrode 9 formed of a conductive material such as a metal, the following effect is obtained. Because a current path at the time of breakdown with the MOSFET in the OFF state is formed below the contact trench 202, that is, a position away from the trench gate structure, damage to the gate insulating film 6 can be prevented. As a result, device destruction occurring at the time of the breakdown can be further suppressed.

It is to be pointed out that the semiconductor device and the method for manufacturing the same according to the present invention are not limited to those embodiments described in the foregoing, and various modifications maybe made therein. There have been described the case where a first conductivity type is the N-type, and a second conductivity type is the P-type by way of example, however, the first conductivity type may be the P-type, and the second conductivity type may be the N-type.

Further, the power MOSFET is shown by way of example as an active element (a semiconductor element) formed in the semiconductor device. However, the semiconductor element is not limited to the MOSFET, and may be, for example, an IGBT (insulated gate bipolar transistor), or a thyristor provided with a trench gate structure. Even in that case, the same effect as obtained in the case of the MOSFET is obtained. Furthermore, the shape of the trench gate structure, as seen in a plan view, is not limited to a stripe-like shape, but may be a polygon or mesh-like shape, in which case, the P-type column regions 16 are formed in the vicinity of the center of respective regions surrounded by the polygons or the mesh. Further, in FIG. 1, and so forth, the trench gate structures plural in numbers are shown, but the trench gate structures may be linked with each other in regions not shown, thereby making up a single trench gate structure as a whole.

In a face-centered cubic lattice such as silicon, with reference to the plane direction, and the crystal axis direction, for example, the (110) crystal plane is equivalent to the (011) crystal plane (collectively called the {110} crystal plane), the (100) crystal plane is equivalent to the (001) crystal plane (collectively called the {100} crystal plane), and the crystal axis direction [110] is equivalent to the crystal axis direction [011] (collectively called a crystal axis direction <110>). Even by utilizing, those equivalent crystal plane, and equivalent crystal axis direction, the same effect can be obtained. Further, a direction in which the trench gate structures disposed in the stripe-like fashion are extended is not limited to the crystal axis direction [110], but may be the crystal axis direction <110> (a direction including the crystal axis direction [110], and all crystal axis directions equivalent thereto) Even in this case, the same effect can be obtained.

Incidentally, there have been described the case where the column structure of the semiconductor device 15 has four column regions 16 that are separated to each other and are separated from the P-type base region 4, some of the column regions 16 may be joined to each other and/or upper column region 16 may be joined to the P-type base region 4. Though at least one column region that is separated from both another column region and the P-type base region is required, and a position that the separated column region is to be formed is preferably selected at a bottom portion of the column structure. In this case, first breakdown point will occur at the PN junction formed between the separated column region and the N-type drift region, and second breakdown point will occur at the PN junction formed between the joined column regions and the N-type drift region, thereby the avalanche current can be concentrated in the column structure.

What is claimed is:

1. A semiconductor device comprising:
a drift region of a first conductivity type, having a {110} crystal plane serving as a main surface thereof;
a trench gate structure formed in a trench and having a gate insulating film and a gate electrode formed therein, the trench being formed in the drift region and having a {100} crystal plane serving as a sidewall surface thereof;
a base region of the second conductivity type provided in the drift region;
a source region of the first conductivity type provided in the base region; and
a plurality of column structures of a second conductivity type provided in the drift region, formed so as to be separated from each other with spacing interposed therebetween, as seen in a plan view,
wherein each of the plurality of column structures includes a plurality of column regions of the second conductivity type separated from each other along a direction vertical to the main surface.

2. The semiconductor device according to claim 1, wherein the trench gate structure comprises a plurality of trench gate structures, as seen in a cross-sectional view, and the plurality of column structures are positioned between the plurality of trench gate structures, respectively, as seen in a plan view.

3. The semiconductor device according to claim 2, wherein the plurality of trench gate structures are disposed in a stripe-like fashion, as seen in a plan view, and a longitudinal direction in which each of the plurality of trench gate structures is extended is a crystal axis direction <110>.

4. The semiconductor device according to claim 1, further comprising:
a plurality of contact trenches formed above each of the column structures; and
a source electrode embedded in the contact trench.

5. The semiconductor device according to claim 4, wherein a bottom part of the contact trench is formed at a position deeper than the base region.

6. A method for manufacturing a semiconductor device, the method comprising the steps of:
forming a drift region of a first conductivity type, having a {110} crystal plane serving as the main surface thereof;
forming a trench, having a {100} crystal plane serving as a sidewall surface thereof, in the drift region;
forming a gate insulating film and a gate electrode in the trench; and
forming a plurality of column structures of a second conductivity type in the drift region, so as to be separated from each other with spacing interposed therebetween, as seen in a plan view, each of the plurality of column structures being formed so as to include a plurality of column regions that are separated from each other along a direction vertical to the main surface.

7. The method for manufacturing a semiconductor device according to claim 6, further comprising the steps of:
forming a base region of the second conductivity type in the drift region; and
forming a source region of the first conductivity type in the base region.

8. The method for manufacturing a semiconductor device according to claim 6, wherein the plurality of column regions are formed by applying ion implantation to the main surface from the direction vertical to the main surface.

9. The method for manufacturing a semiconductor device according to claim 8, wherein the ion implantation is applied plural times, and respective ion implantations differ from each other in acceleration energy.

10. The method for manufacturing a semiconductor device according to claim 8, further comprises the steps of forming a contact trench before the forming a plurality of column structures, wherein the ion implantation is applied through the contact trench.

11. The method for manufacturing a semiconductor device according to claim 10, wherein a bottom part of the contact trench is formed at a position deeper than the base region.

12. The method for manufacturing a semiconductor device according to claim 11, further comprises the steps of forming a source electrode embedded in the contact trench.
